(19) United States
(12) Patent Application Publication
(10) Pub. No.: US 2014/0209156 A1
(43) Pub. Date: Jul. 31, 2014

(54) BIPOLAR DIODE HAVING AN OPTICAL QUANTUM STRUCTURE ABSORBER

(71) Applicant: Andreas Paul Schüppen, Aachen (DE)

(72) Inventor: Andreas Paul Schüppen, Aachen (DE)

(21) Appl. No.: 13/997,323

(22) PCT Filed: Dec. 23, 2011
(86) PCT No.: PCT/EP2011/006535

§ 371 Date: Feb. 13, 2014

(30) Foreign Application Priority Data
Dec. 24, 2010 (EP) 10016068.8

(51) Int. Cl. H01L 31/0745; H01L 29/04; H01S 5/32; H01L 29/165

(52) U.S. Cl. CPC H01L 31/0745; H01L 29/165; H01L 29/04; H01S 5/321
USPC 136/255; 257/197; 257/52; 257/75; 372/44.01

(57) ABSTRACT

The invention relates to a novel silicon-based, single-stage solar cell which, instead of converting light in a bulk semiconductor material, generates electrical energy within a very thin quantum structure that is deposited. The layer sequence itself consists of a three-fold hetero structure as an absorber, which is embedded into the space charge region of a pn-junction and is based on quantummechanical effects.

Therein, the layer is preferably deposited by a CVD or the like method. High efficiencies of above 30% were initially measured on small samples on silicon.

### STATE OF THE ART

Today, a couple of physical methods exist for generating electrical energy from sun light. To begin with, mono- or multicrystalline silicon solar cells are fabricated in the photovoltaic (PV) industry based on standard pn-junction diodes. These silicon solar cells reach about 23% efficiency in research and 17-20% in production. The silicon solar cells are advantageous in view of simplicity, economics, environmental reasons and proven life-time. Further, there exist thin film silicon cells, which are fabricated by chemical vapour deposition (CVD) of one or several pn-junctions on glass. These solar cells reveal 5-8% efficiency only. Therein, a problem of this technology seems to be the long term stability. Often, this film cells consist of two stacked pn-junctions, so called tandem cells. Further, there exist II-VI and III-V based solar cells. Thin film cells built from cadmium telluride (CdTe) or cadmium indium gallium di-selenide (CIGS) seem to be very cost efficient and reach efficiencies of up to 20% in research. However, the materials used are controversially discussed because of being seldom and environmental toxins.

GaAs based solar cells are well proven in space technology. They are often provided as so-called triple junction cells comprising three stacked pn-junction respectively converting a different wave band of the sun light to a current.

The state of the art and its efficiency is summarized in the following table:

| Material | World Record | Production |
|---|---|---|
| Crystalline Silicon | 23.2% | 16-21% |
| Crystalline III-V | 42.8% | 30-35% |
| Thin Film a-Si/c-Si | 15.0% | 5-8% |
| Thin Film CIGS | 19.9% | 9-12% |
| Thin Film CdTe | 15.6% | 7-8% |
| Organic Solar Cells | 6.0% | — |

Independently of the material and the production process, today's solar cells are all based on a standard diode, namely consist of one or a plurality of pn-junctions. These diodes are formed from a connected n-doped and p-doped region internally of a semiconductor material. Due to the concentration gradient between the electron rich (n) and the hole rich (p) layer, a space charge region and an electric field is observed at the transition. At the edge of the so-called space charge region, a voltage can be measured, the so-called diffusion voltage. When light penetrates into the semiconductor material, electron-hole pairs are generated (photovoltaic effect). The electron-hole pairs generated in the space charge region are moved to the outer contacts of the solar cell by the diffusion voltage. When a load is connected, an electric current results and energy is generated, thus. A disadvantage of this type of diode for photovoltaic current generation is that the diffusion voltage depends from the doping of the n- and p-regions and that the thickness of the space charge region is inversely proportional to the doping. This means that an increase of the diffusion voltage leads to a reduction of the space charge region in which photons can generate electron-hole pairs effectively. Additionally, the light must reach the space charge region in order to generate a current. The light should not be absorbed previously or exit without an interaction with valence electrons of the atoms of the space charge region. Hence, standard solar cells used today only use a small part of the spectrum of the sun light. Some of the generated charges will, for instance due to being generated outside of the space charge region, not contribute to the current, because they recombine before reaching the contacts.

At the end of the 1970s, quantum structures comprising a plurality of hetero-transitions were suggested in order to overcome the problem described above. However, all these ideas were to complex and not reproducible for real production processes. So, until today, none of these approaches has been implemented in industry.

In FIG. 1a, the standard pn-junction solar cell is shown. Typically, the pn-junction is located several hundred nanometres (nm) below the surface of the solar cell. The light energy will be used only partly. Since for instance infrared light has a too long wave length, it will not generate electron-hole pairs; the photon energy is only used partly. The most energy can be generated in the wave length range between 900-1100 nm, close to the band gap energy of silicon. Blue and violet light will generate electron-hole pairs; however, the photon energy is too high, which means that a lot of photon energy will be lost by thermalisation, namely by a loss of energy due to dissipation. Theoretical calculations show that efficiencies above 33% can not be expected for an ideal one-stage solar cell.

In a mono- and multi crystalline solar cell, a photon can generate an electron-hole pair which is moved by an electric field to the contacts. By a special solution of Maxwell's equation—the Poisson equation—it can be shown that the curvature of the band edge is responsible for the movement of the charges. The disadvantages and losses due to physical effects in standard pn-junction solar cells can be summarized as follows:
The spatially distributed light absorption in the silicon, namely the charge generation in flat band regions, which leads to a recombination of the electron-hole pairs
Recombination of the electron-hole pairs in the space charge regions and band regions—life time of the charges
Thermalisation of the electron-hole pairs in the flat band regions
Ohmic losses in the flat band regions and contact regions
Losses due to contact resistances
Shading by the front-contacts
Reflection at the surface—mainly for high energy radiation—texturing is necessary
Dependency of the light absorption from the frequency of the light
Temperature dependency of the efficiency due to a band gap reduction and increased recombination, namely reduced life time−intrinsic conduction
The quantum efficiency is limited to 1

The problem the present invention is to solve is to provide a highly-efficient solar cell appropriate for production, which does not have the disadvantages described above. Thereto, a quantum structure is embedded into a pn-junction, which overcomes the coupling between diffusion voltage or open circuit voltage V_{OC} and the size of the space charge region or effective absorption layer. Further, the thermalisation of generated electrons and the recombination of generated charges shall be reduced. Additionally, a material with a higher light absorption shall allow a reduction of the thickness of the active layers. At the same time, the efficiency should be increased. The innovative solar cell shall be cost efficiently producible.

### DESCRIPTION OF THE INVENTION

In contrast to state of the art solar cells (FIG. 1a), a diode having a band structure as shown in FIG. 2 is suggested. The new solar cell consists of two tunneling barriers which enclose a region of for instance silicon germanium. This triple hetero structure is embedded into a pn-junction. The embedded layers consist of only three regions; a large band gap material, eg. SiC, a small low band gap material, eg. SiGe, and a large band gap material again. The surrounding material has a medium band gap and could for example be silicon. Such a typically epitaxial structure has been described in [1].

Since Silicon Germanium, for instance 33% Germanium, has a hundredfold higher light absorption than pure silicon for all wave lengths of interest, the thicknesses of the relevant layers can be about a 100 times thinner than in a standard silicon solar cell, wherein the light absorption and quantum efficiency is unchanged. As shown by the energy band structure, sub bands are generated when the layer thickness is appropriate. Hence, each incident photon will find an optimum sub band combination which converts the photon energy to one or several electron-hole pairs. The external field, which results from the diffusion voltage of the enclosing pn-junction, lets electrons tunnel into the conduction band of the n-region and holes into the p-region. By this new approach most of the loss mechanisms will be reduced in the new solar cell:
The penetration depth of the light is spread over a few nanometers only, namely the thickness of the thin SiGe layer,
Recombination and life time of the charges are negligible for the new solar cell, because generated charges will all reach the band regions.
Thermalisation will presumably be no issue, because electrons and holes will reach the contact regions from the sub bands—corresponding energy levels—due to the tunnel effect and the electric field.
Reflection of light will be of minor importance, because each photon penetrating a few nm at the surface of the new cell is converted into electrical energy. This is also advantageous because of being more independent from the incident angle of the light.
The new solar cell is less temperature dependent, because the SiGe layer is very thin and at the same time doped up to a status of degeneration so that a change in band gap has only a minor impact on the solar cell. The quantum mechanical tunnel effect is almost independent of the temperature.
The diffusion voltage can be adjusted independently of the light absorber.
The band structure and measurements performed at test structures indicate that quantum efficiencies above one can be expected. Electron-hole pairs generated for instance by UV light can generate other electron-hole pairs when dropping to lower energy levels.
The spectral sensibility SR of the cell will be higher than in case of a standard solar cell due to the small thickness of the active layer in which light of different wave lengths is generated.
Due to the tunnelling barriers for holes and electrons, a back diffusion of generated charges will be suppressed almost completely.

### DESCRIPTION OF THE DRAWINGS

FIG. 1a: Layer sequence of a standard solar cell

FIG. 1b: Schematic energy band structure for a one stage solar cell, showing the conduction band edge E_{C}, the valence band edge E_{V} and the Fermi level E_{F} and incident red and UV light; • electron, ∘ hole, SCR (space charge region).

FIG. 2a: Layer sequence of the bipolar device: 1 p-doped region, 2 and 4 large band gap material, 3 semiconductor material with small band gap, 5 n-type material layer.

FIG. 2b: Schematic energy band structure of the new bipolar device with incident red and UV light. • electron, ∘ hole, SCR (space charge region).

FIG. 3: Spectrum resonance measurements (SR) of a standard multi crystalline solar cell and the new cell. The measurements show the quantum efficiency to be above one for wave lengths from 300-700 nm.

### DESCRIPTION OF THE FIGURES AND FUNCTIONALITY

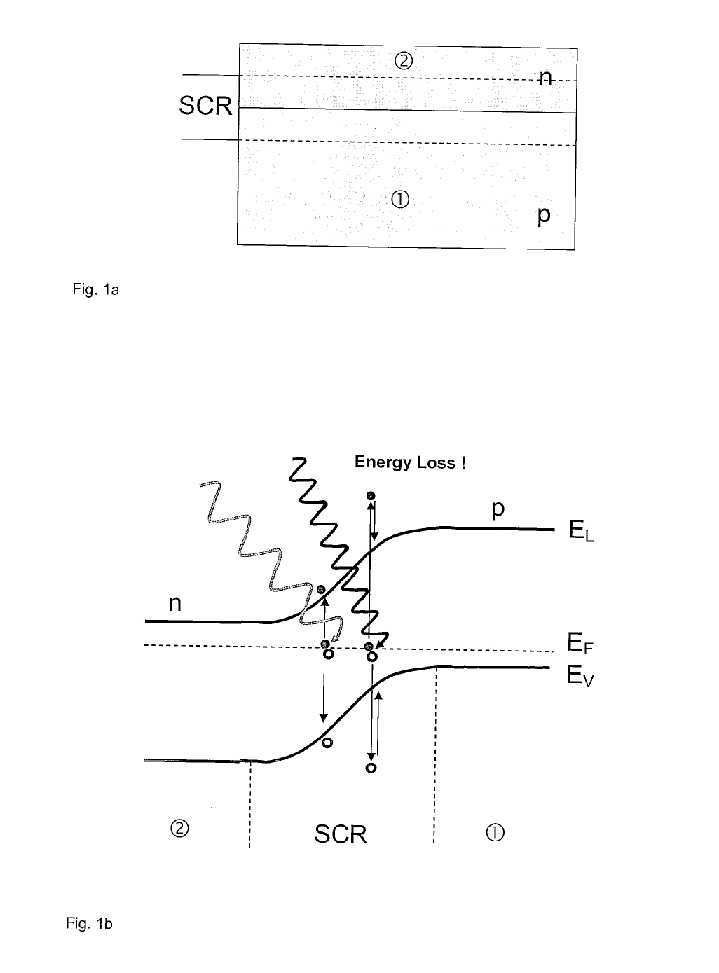

FIG. 1a schematically shows a standard pn-junction solar cell. The layer 1 is often a p-doped wafer as a basic material. The n-doped layer 2 will normally be generated by Phosphorus doping into the substrate and has a concentration gradient which is not shown in the drawings. At the transition between p- and n-region, the space charge region (SCR) is located. In the SCR, a region without free charges and an electrical field result due to the large gradient in concentration between n and p. For the sake of simplicity, the contacts and the gradient of doping resulting from the doping of the n-region are not shown. In the energy band model, this leads to a deflection of the conduction band E_{L} and of the valence band E_{V} without a voltage being applied, which is schematically shown in FIG. 1 b. The resulting diffusion voltage which is approximately equivalent to the open circuit voltage U_{CO} is the difference between the conduction band edge in the n-region 2 and the conduction band edge in the p-region 1. Primarily, it depends from the doping of the two regions. Typically, it is around 0.6 V in case of solar cells. The SCR has a width of around several 100 nm in case of typical solar cells. Only in the region in which the bands have a gradient, namely the conduction and the valence band being not parallel to the Fermi level, electron-hole pairs generated are moved to the contacts of the diode by the electrical field and contribute to the current flow when a load is connected. Due to the coupling of the diffusion voltage, the width of the SCR and the doping, the possibilities for optimizing such a solar cell are limited. When light is incident onto this solar cell, which has a wave length below approximately 1000 nm, electron-hole pairs are generated in the SCR. However, light having a large wave length, for instance infrared light, does not have enough energy for activating the valence electrons and convert the photonic energy into electrical energy. Light having a shorter wave length has too much energy so that the electron-hole pairs generated drop back to the conduction or valence band level prior to having reached the contacts. Therein, only heat is generated.

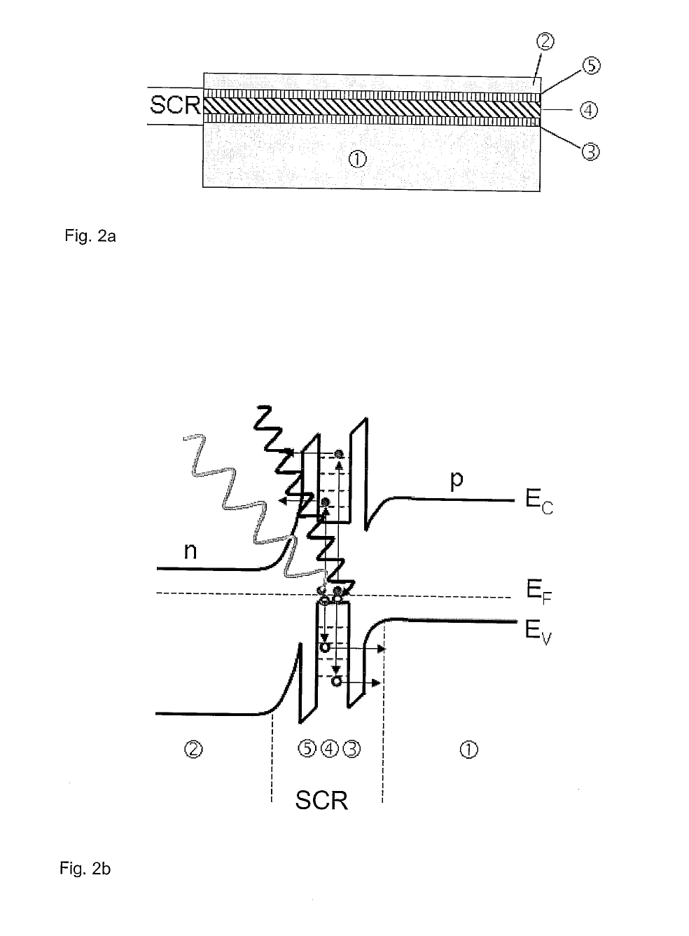

FIG. 2a schematically shows the layer structure of the new solar cell disclosed here. By introducing the tunnel barriers made of a large gap-material, for instance SiC or SiO₂, the diffusion voltage and the outer doping are decoupled. As in case of a conventional cell, the basic material can be a p-doped wafer, for instance Si. However, instead of doping an n-region, at least four further layers are deposited epitaxially or by the like depositing method. First, a layer having a thickness of 1 to 10 nm of a material having a large band gap 3 is deposited, for instance SiC; then, a material having a small band gap 4, for instance SiGe, is deposited having a thickness between 5 and 25 nm; then, again a material having a large band gap is deposited having a thickness of 1 to 10 nm. Therein, the thicknesses of the layers 3 and 5 must be adapted for meeting tunneling conditions for holes and electrons. Advantageously, the layer 4 is adapted in its thickness such that so-called sub bands result. The layer 2 is n-doped and is a contact layer, but is also used for an adaption of the diffusion voltage required.

FIG. 2b shows the resulting band structure of such a solar cell. A quantum structure is embedded into the two connection regions 1 and 2, which comprises to tunnel barriers 3 and 5 and a quantum valley 4 in between, the quantum valley being provided from a material having a smaller band gap. In case that the thickness of the layer 4 is optimized, presumably sub bands result, namely quantized energy levels, as shown in FIG. 2b.

Due to the embedded structure, the n- and p-doped connecting regions 1 and 2 are separated from the absorber structure so that the diffusion voltage is freely adjustable within a certain range. Assuming that the two surrounding layers are made of silicon, a diffusion voltage of up to 1.1 V can be adjusted. This would be almost twice as much as in case of conventional solar cells.

With light being incident on such a structure, electron-hole pairs are generated from the energy gap of the material having a small band gap on, for instance 1500-1700 nm for SiGe. Due to the diffusion voltage between 1 and 2, the electrons, after being generated, tunnel into the n-region 2 and holes tunnel into the p-region 1. Therefrom, a current flow results when a load is connected to the cell. Therein, almost every light wave length fits to a combination of energy levels so that losses due to thermalisation, which occur in conventional solar cells, are reduced. Further, the quantum efficiency is presumably above 1; electron-hole pairs having for instance been generated by a highly energetic UV light and dropping back fit to levels below and can generate further electron-hole pairs there. Basically, the new solar cell operates like an inverse Laser. The light absorption occurring in a depth of only a few nanometers only is improved also insofar as for instance Si₇₅Ge₂₅ has, over the hole wave length region, an absorption which is 20-50 times higher than in case of pure silicon. Thus, assuming that the SCR of a standard solar cell has a width of around 500 nm, an SCR having a width of 10-25 nm will be at least as effective as a conventional cell.

Due to having a comparable absorption, a broad usable light wave length spectrum of about 1700 nm-300 nm, a higher diffusion voltage, less thermalisation and a larger medium current density, it can be assumed that the power efficiency is significantly higher than in case of a standard solar cell. With small samples, this has been shown already.

A plurality of solar cell samples having a size of 1×1 cm² have been fabricated from 200 mm wafers to demonstrate the physical effects and functions described in this disclosure. The solar cells show an improved efficiency, a reduced temperature dependence and a reduced dependency from the incident angle.

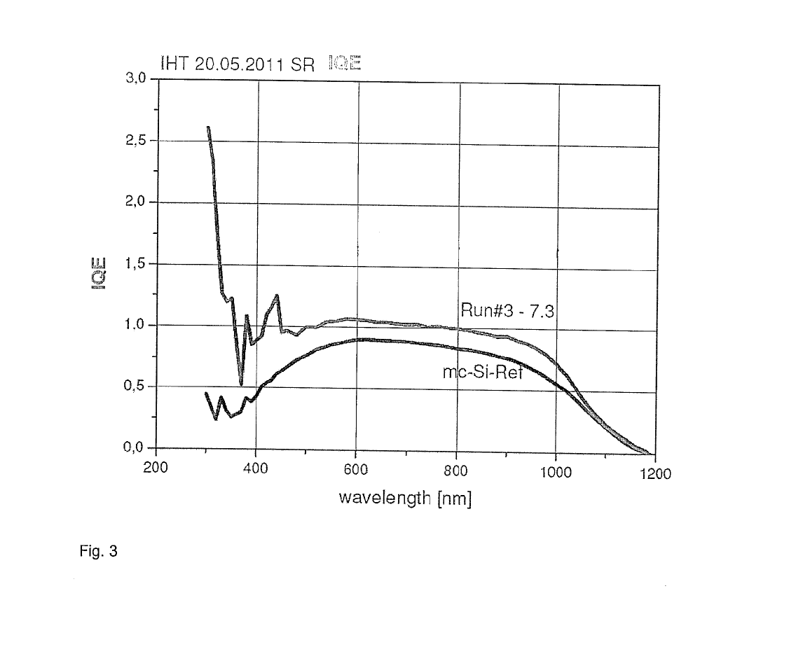

A typical example is shown in FIG. 3, namely a spectrum resonance measurement (SR) of two diodes. The lower curve shows the SR-response of a standard multi crystalline solar cell, and the upper curve shows the SR-measurement of a solar cell disclosed here. Particularly in the UV and blue light spectrum, significant differences result. In contrast to a conventional silicon solar cell having a quantum efficiency of not more than 50% in the UV-region, quantum efficiencies above 1 could be measured with the diodes disclosed here. Further, the upper curve shows minimum and maximum values in a frequency region of 300-700 nm which may result from sub bands.

In simple words, in this region, a photon generates more than one electron holepair so that a higher current and efficiency can be expected in case of an optimized diode structure.

### LITERATURE

[1] DE 10 2005 047 221 A1, 2005
[2] Albert Einstein: Über einen die Erzeugung und Verwandlung des Lichtes betreffenden heuristischen Gesichtspunkt. In: Annalen der Physik. 322, Nr. 6, S. 132-148, 1905
[3] Ibach-Lüth, Festkorperphysik, Einfuhrung in die Grundlagen, 2002
[4] M. S. Sze, Physics of Semicconductor Devices, Wiley & Sohn, 1981
[5] Rubin Braunstein, Arnold R. Moore and Frank Herman, Intrinsic Optical Absorption in Germanium-Silicon Alloys, Phys. Rev. 109, 695-710, 1958
[6] Richard Feynman: QED. Die seltsame Theorie des Lichts und der Materie ISBN 3-492-21562-9-1987

1. A bipolar semiconductor device for converting light into electrical current or electrical current into light, said device comprising:
a) a first layer consisting of p-doped semiconductor material with a band gap X,
b) a second layer consisting of a material with a larger band gap Y and having a thickness such that charge carriers are able to tunnel therethrough,
c) a third layer consisting of a material with a smaller band gap Z and of a material having a high light absorption,
d) a fourth layer consisting of a material with a larger band gap Y and having a thickness such that charge carriers are able to tunnel therethrough, and
e) a fifth layer consisting of a n-doped semiconductor material having a band gap X and is sufficiently thin that incident light can reach the layers of b), c), d), and e).

2. The device of claim 1, characterized in that the first and fifth layers consist of silicon (Si), the second and fourth layers consist at least of silicon (Si) and carbon (C) and the third layer consists of silicon germanium (SiGe).

3. The device of claim 1, characterized in that the third layer is sufficiently thin that there are energy sub bands between the second and the fourth layer.

4. The device of claim 1, characterized in that the layers are deposited by one of chemical vapour deposition or epitaxy.

5. The device of claim 1, characterized in that the layer sequence of claim 1 is formed by materials of the periodic table groups II, III, V, and VI.

6. The device of claim 1, characterized in that the layers are grown on at least one of a mono- or multi-crystalline silicon wafers, silicon foil, glass and metal-coated glass.

7. The device of claim 1, characterized in that the layers are deposited amorphous or polycrystalline on a carrier material.

8. The device of claim 1, characterized in that the first layer is n-doped and the fifth layer is p-doped.

9. The device of claim 1, characterized in that the layers for one of a solar cell or a laser.

10. The device of claim 1, wherein Y>X and Y>Z.
